(19) United States
(12) Patent Application Publication
(10) Pub. No.: US 2025/0237366 A1
(43) Pub. Date: Jul. 24, 2025

(54) Light Module for a Motor Vehicle and Method for Producing a Light Module

(71) Applicant: ZKW Group GmbH, Wieselburg (AT)

(72) Inventors: Stefan ETLINGER, St. Pölten (AT); Leopold PRITZL, Bergland (AT); Eva STEINER, Ferschnitz (AT)

(21) Appl. No.: 19/029,294

(22) Filed: Jan. 17, 2025

(30) Foreign Application Priority Data
Jan. 18, 2024 (EP) 24152668.0

(51) Int. Cl. F21S 41/29; F21S 41/141; F21S 41/24; F21Y 115/10

(52) U.S. Cl. CPC F21S 41/29; F21S 41/141; F21S 41/24; F21Y 2115/10

(57) ABSTRACT

A light module (1) for a motor vehicle, in particular a motor vehicle headlight, wherein the light module (1) includes: a printed circuit board (2), at least one light unit (3) arranged flat on one side of the printed circuit board (2) having a light exit surface (3a) for emitting light, wherein the light unit (3) preferably comprises at least one LED light source (3b), wherein a printed circuit board plane (yz) is formed by said side of the printed circuit board (2), wherein the printed circuit board (2) has at least one spacer element receiving opening (4), which is arranged in the vicinity of the at least one light unit (3), wherein the at least one spacer element receiving opening (4) passes through the printed circuit board (2) and is configured to receive a spacer element (5), as well as at least one light guide (6).

### CROSS-REFERENCE TO RELATED APPLICATIONS

This application claims priority to European Patent Application No. 24152668.1, filed Jan. 18, 2024, which is incorporated herein by reference.

### FIELD OF THE INVENTION

The invention relates to a light module for a motor vehicle, in particular a motor vehicle headlight, wherein the light module comprises the following: a printed circuit board, at least one light guide, and at least one light unit arranged flat on one side of the printed circuit board having a light exit surface for emitting light, wherein the light unit preferably comprises at least one LED light source, wherein a printed circuit board plane is formed by said side of the printed circuit board.

### BACKGROUND

Light guides can be used to guide the light emitted by the light unit from the printed circuit board towards a desired emission region and to produce a desired light distribution within the emission region. For this purpose, the light guides are typically supported above the light unit directly on the printed circuit board such that a light entry surface of the light guide is associated with the light unit.

Such a design results in an air gap between the light entry surface and the light unit. In practice, the object of creating light modules with a higher power density and therefore generally lower costs is sometimes diametrically opposed to the technical task of achieving a high degree of durability of the light unit. For example, a higher power density often results in an increase in temperature in components, which negatively impacts the durability of electronic components. Sophisticated cooling systems are therefore used in practice to achieve higher power densities while maintaining the same temperature load. Attempts are also constantly being made to increase the efficiency of the light sources used in the light unit.

### SUMMARY OF THE INVENTION

One object of the invention is to create a light module that enables the power density to be increased.

This object is achieved with a light module of the type mentioned in the introduction in which, according to the invention, the printed circuit board has at least one spacer element receiving opening, which is arranged in the vicinity of the at least one light unit, wherein the at least one spacer element receiving opening passes through the printed circuit board and is configured to receive a spacer element, wherein the light module further has at least one spacer element, which is arranged in at least one spacer element receiving opening, wherein the at least one spacer element has at least two sections, namely a holding section passing through the spacer element receiving opening and at least one support section arranged on one end of the holding section, which support section is widened compared to the holding section and secures the spacer element from being pushed through the spacer element receiving opening, wherein the support section is arranged on the same side of the printed circuit board as the at least one light unit and is delimited on its end facing away from the printed circuit board by a flat support face, wherein this support face is oriented substantially parallel to the printed circuit board plane, wherein the light guide has a light entry surface, which faces the light unit for receiving light, wherein the light entry surface of the light guide is at least partially surrounded by at least one support region of the light guide, which support region of the light guide is supported on the support face of the spacer element for fixing a defined normal distance of the light entry surface of the light guide in relation to the light unit.

By using the spacer element, a defined minimum distance to the light guide can be specified, which is maintained regardless of the manufacturing and positioning accuracy of the light guide. In this way, the temperature on the light guide can be reduced in normal operation by around 3 to 4° C. compared to a variant in which the light guide is supported directly on the printed circuit board. In detail, the size of the air gap can be specifically influenced by selecting the embodiment of the spacer element. In addition, projections on the light guide can be reduced or dispensed with entirely.

In particular, it may be provided that the support section of the spacer element protrudes further in the normal direction to the printed circuit board plane from the printed circuit board than the light exit surface of the light unit such that the support face protrudes beyond the light exit surface in the normal direction. Even if there are therefore no projections arranged on a corresponding light guide and the entry surface extends flat over the entire cross-section of the light guide, the light guide does not touch the light unit in this variant.

It may further be provided that at least one projection, preferably two projections are formed in the support region of the light guide, which protrude in the direction of the support face of the spacer element from the light guide and are supported on the support face.

In particular, it may be provided that the holding section of the spacer element is designed in such a way that it fills the spacer element receiving opening in a form-fitting manner. This can ensure particularly good retention of the spacer element.

Furthermore, it may be provided that the at least one light unit is surrounded by at least two, preferably exactly two, spacer element receiving openings, wherein these spacer element receiving openings are arranged spatially around the light unit in such a way that if there are exactly two spacer element openings in the vicinity of the light unit, the centre point of a notional connecting line between the spacer element openings substantially coincides with the geometric centre of the light exit surface of the light unit, and/or if there are three or more spacer element openings in the vicinity of the light unit, the centre of a notional polygon substantially coincides with the geometric centre of the light exit surface of the light unit, wherein the notional polygon is formed in such a way that each spacer element opening present in the vicinity of the light unit forms a corner of the polygon and each corner has a straight connection to the two closest corners. This creates a particularly mechanically stable mounting method. If there are three spacer element openings in the vicinity of the light unit, a triangle would thus be formed, if there are four openings, a square, etc. It is advantageous if the geometric figure formed in this way encloses the light exit surface of the light unit. In the event of circular or square light-emitting surfaces, it is therefore advantageous for the openings to be evenly spaced.

“Vicinity of the light unit” can be understood to mean a distance of no more than 3 mm measured between the light unit (i.e. an edge point thereof closest to the opening) and the spacer element opening (also the edge point closest to the light unit).

In particular, it may be provided that the light module has two or more light units, wherein the two or more light units are each associated with at least one, two or more spacer element receiving openings, each with a spacer element accommodated therein, and a light guide. It may further be provided that the support section and the holding section of the spacer element are respectively substantially cylindrical with a common longitudinal axis.

In particular, it may be provided that the distance between a spacer element receiving opening and the nearest point of an associated light unit is no more than 3 mm, in particular between 1.5 mm and 3 mm. The distance can typically be 2 mm, for example.

It should also be noted that any technical feature that has been mentioned for an individual element may also apply to a plurality of or all of the elements of the same element type. That means that the aforementioned distances, geometric arrangements to one another etc. may be applicable to one element, two or more or even to all elements.

It may further be provided that the spacer element receiving opening is designed as a hole having a circular hole diameter of between 1 mm and 2 mm. The diameter can typically be 1.2 mm, for example.

In particular, it may be provided that the cross-sectional area of the support section is at least four times the cross-sectional area of the holding section of the spacer element.

It may further be provided that the holding section of the spacer element is firmly fixed in the spacer element receiving opening.

In particular, it may be provided that the spacer element also has a securing section, which securing section is arranged on the end of the holding section opposite the support section, wherein the securing section is widened relative to the holding section. This can be done, for example, by spreading or heat staking.

Furthermore, the invention relates to a method for producing a light module according to the invention, wherein the method comprises the following steps:
a) providing a printed circuit board, which is equipped with at least one light unit, wherein the printed circuit board has at least one spacer element receiving opening, which passes through the printed circuit board and is configured to receive a spacer element,
b) providing at least one spacer element, wherein the at least one spacer element has at least two sections, namely a holding section passing through the spacer element receiving opening and at least one support section arranged on one end of the holding section, which support section is widened compared to the holding section,
c) inserting the at least one spacer element into the at least one spacer element receiving opening,
d) establishing a connection between the at least one spacer element and the at least one spacer element receiving opening, which secures the at least one spacer element against a displacement in a normal direction to the printed circuit board,
e) positioning a light guide, which has a light entry surface, on the printed circuit board in such a way that the light entry surface faces the light unit for receiving light, wherein the light entry surface of the light guide is surrounded by at least one support region of the light guide, which support region of the light guide is supported on the support face of the spacer element for fixing a defined normal distance of the light entry surface of the light guide in relation to the light unit.

The connection according to step d) can be made, for example, by bonding, heat staking or mechanical spreading.

In particular, it may be provided that the light guide is spatially fixed in the position according to step e) in relation to the printed circuit board. This can be achieved, for example, by a fixed connection in a common housing, on the printed circuit board and/or other components that are fixedly connected to the printed circuit board.

It may further be provided that the at least one spacer element is inserted in step c) in an automated manner using optical detection of the at least one spacer element receiving opening. For example, predefined geometric shapes and sizes of openings on the printed circuit board may be provided exclusively for spacer element receiving openings, e.g. in the form of circular holes with a specific diameter, which can then be automatically detected and assigned.

The support section of the spacer element can also be oval or have a cross-section corresponding to the shape of an elongated hole (i.e. such that it can fill an elongated hole in a form-fitting manner). An oval-shaped or elongated hole-shaped embodiment has the advantage that in the longitudinal direction of the geometric shape of the support section, more tolerance is created in terms of positioning, and in the narrow direction less space is required by the spacer element. This is particularly advantageous if there are different accuracies/tolerances in the two different directions of the printed circuit board plane during assembly or production and it is possible to respond to this by designing the shape and positioning the support sections accordingly.

### BRIEF DESCRIPTION OF THE DRAWINGS

The invention is outlined in more detail below based on an exemplary and non-limiting embodiment, which is illustrated in the figures.

FIG. 1A shows a schematic illustration of a light module according to the invention without a light guide.

FIG. 1B shows the light module according to FIG. 1A in a view from diagonally below.

FIG. 1C shows a top view of the light module according to FIG. 1A and 1B.

FIG. 2A shows a perspective view of the light module according to FIG. 1A to 1C including a light guide.

FIG. 2B shows a sectional view of the light module according to FIG. 2A.

FIG. 3 shows a perspective illustration of the light module according to FIG. 2A including a heat sink.

FIG. 4 shows a perspective illustration of the light module according to FIG. 3 including a section of a frame structure.

FIG. 5A shows a schematic illustration of an exemplary assembly process.

FIG. 5B shows a sectional view of an exemplary connection process.

### DETAILED DESCRIPTION OF EMBODIMENTS

In the following figures, unless otherwise stated, the same reference numbers denote the same features.

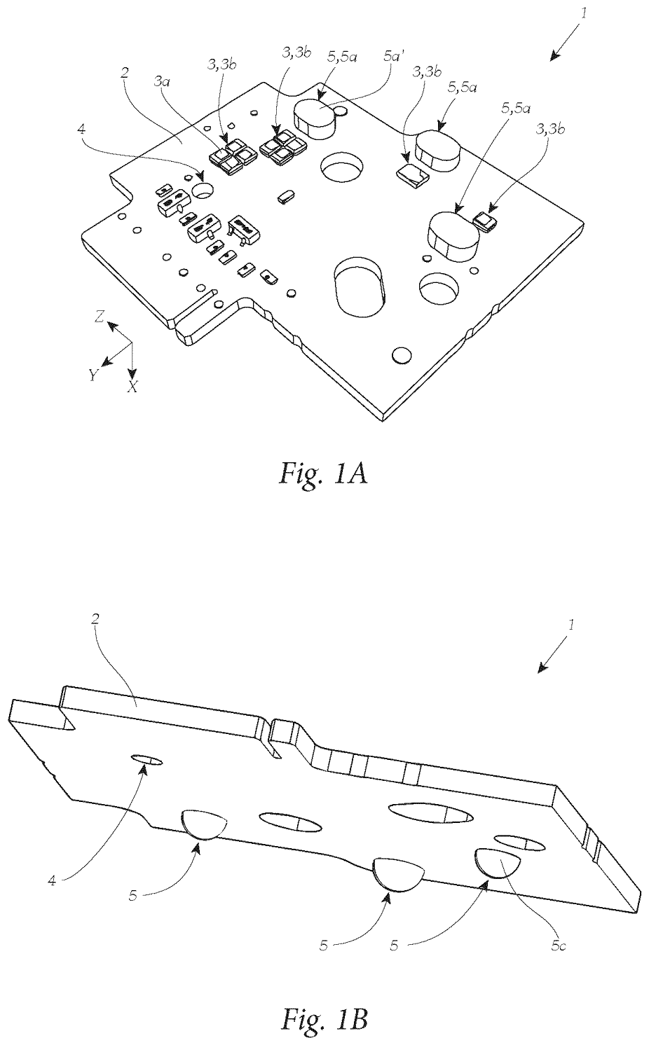

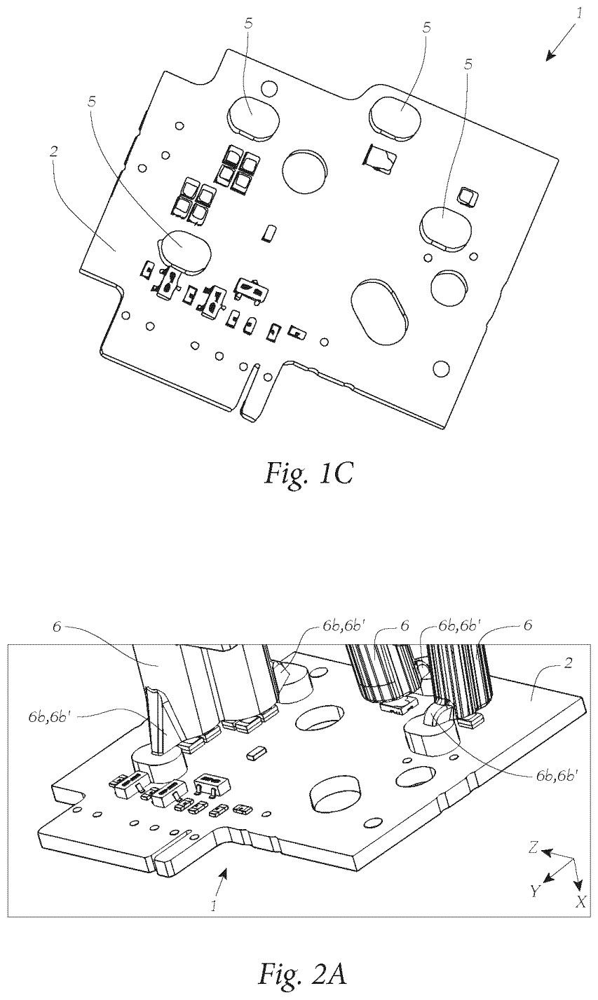

FIG. 1A shows a schematic illustration of a light module 1 according to the invention without a light guide 6 (shown from FIG. 2a). The light module 1 is suitable for application on/in a motor vehicle and can in particular be used in a motor vehicle headlight. The light module 1 comprises a printed circuit board 2 as well as at least one light unit 3 arranged flat on one side of the printed circuit board 2 having a light exit surface 3a for emitting light. In the present case, the light unit 3 has, for example, LED light sources 3b, wherein in a left-hand upper region in FIG. 1a, two groups of four are shown, and to the right, two individual LEDs 3b are shown. A printed circuit board plane yz is formed by the side of the printed circuit board 2 on which the light sources 3b are arranged. The axis x is oriented orthogonally thereto and thus protrudes normally from the printed circuit board plane yz.

In FIGS. 1A and 1B, one of the four spacer elements 5 provided in principle in this example is deliberately not shown in order to show that the printed circuit board 2 has spacer element receiving openings 4, and an associated opening 4 for each spacer element 5. These openings 4 are arranged in the vicinity of an associated light unit 3, wherein the at least one spacer element receiving opening 4 passes through the printed circuit board 2 and is configured to receive a spacer element 5.

As already mentioned, the light module 1 further has spacer elements 5, which are respectively arranged in a spacer element receiving opening 4. The at least one spacer element 5 has at least two sections, namely a holding section 5b (see FIG. 2B) passing through the spacer element receiving opening 4 and at least one support section 5a arranged on one end of the holding section 5b, which support section is widened compared to the holding section 5b and secures the spacer element 5 from being pushed through the spacer element receiving opening 4. The support section 5a is arranged on the same side of the printed circuit board 2 as the at least one light unit 3. It is delimited on its end facing away from the printed circuit board 2 by a flat support face 5a′. This support face 5a′ is oriented substantially parallel to the printed circuit board plane yz. It may be provided that the light module 1 has two or more light units 3, wherein the two or more light units 3 are each associated with at least one, two or more spacer element receiving openings 4, each with a spacer element 5 accommodated therein, and a light guide 6.

FIG. 1B also shows that the spacer element 5 also has a securing section 5c, which securing section 5c is arranged on the end of the holding section 5b opposite the support section 5a, wherein the securing section 5c is widened relative to the holding section 5b. The widening can, for example, be achieved by spreading or heat staking.

FIG. 2A shows a perspective view of the light module 1 according to FIG. 1A to 1C incl. light guide, The light module 1 has three light guides 6, by way of example. Each light guide has a light entry surface 6a (see FIG. 2b), which faces the light unit 3 in question for receiving light. The light entry surface 6a of the light guide 6 is at least partially surrounded by at least one support region 6b of the light guide 6. The support region 6b of the light guide 6 is supported on the support face 5a′ of the spacer element 5 for fixing a defined normal distance d of the light entry surface 6a of the light guide 6 in relation to the light unit 3.

FIG. 2B shows a sectional view of the light module 1 according to FIG. 2A. FIG. 2A and FIG. 2B show that the support section 5a of the spacer element 5 protrudes further in the normal direction to the printed circuit board plane yz from the printed circuit board 2 than the light exit surface 3a of the light unit 3 such that the support face 5a′ protrudes beyond the light exit surface 3a in the normal direction-x. In addition, it is shown, for example, that it may be provided that at least one projection 6b′, preferably two projections 6b′ are arranged in the support region 6b of the light guide 6, which protrude in the direction of the support face 5a′ of the spacer element 5 from the light guide 6 and are supported on the support face 5a′. The holding section 5b of the spacer element 5 is preferably designed in such a way that it fills the spacer element receiving opening 4 in a form-fitting manner.

It may be provided that the at least one light unit 3 is surrounded by at least two, preferably exactly two, spacer element receiving openings 4, wherein these spacer element receiving openings 4 are arranged spatially around the light unit 3 in such a way that if there are exactly two spacer element openings 4 in the vicinity of the light unit 3, the centre point of a notional connecting line between the spacer element openings 4 substantially coincides with the geometric centre of the light exit surface 3a of the light unit 3, and/or if there are three or more spacer element openings 4 in the vicinity of the light unit 3, the centre of a notional polygon substantially coincides with the geometric centre of the light exit surface 3a of the light unit 3, wherein the notional polygon is formed in such a way that each spacer element opening 4 present in the vicinity of the light unit 3 forms a corner of the polygon and each corner has a straight connection to the two closest corners. It may further be provided that the holding section 5b of the spacer element 5 is firmly fixed in the spacer element receiving opening 4.

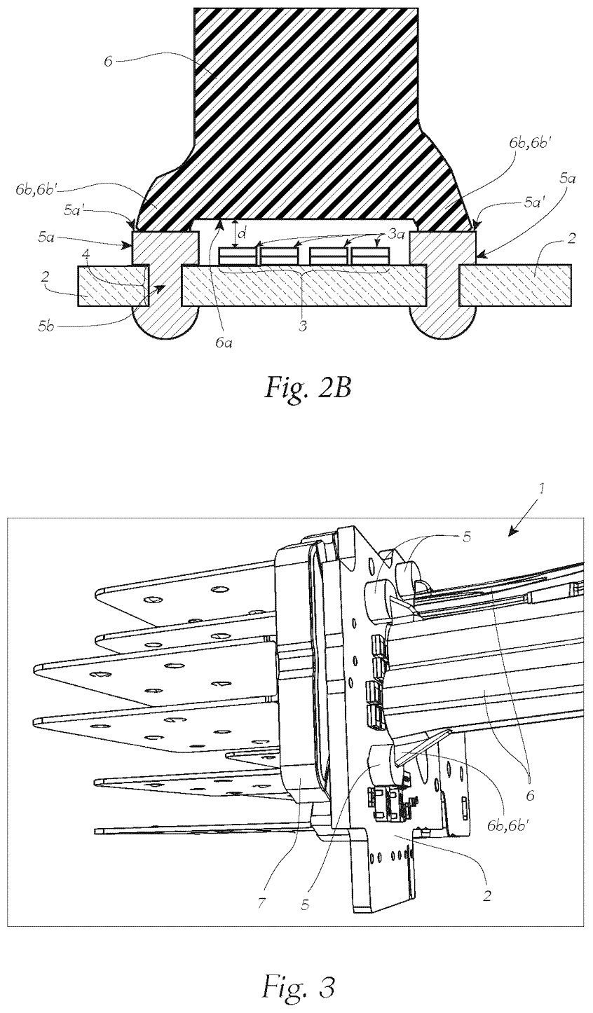

FIG. 3 shows a perspective illustration of the light module 1 according to FIG. 2A incl. a heat sink 7, which is configured to dissipate heat loss that occurs on the printed circuit board 2 or the electronic components arranged thereon.

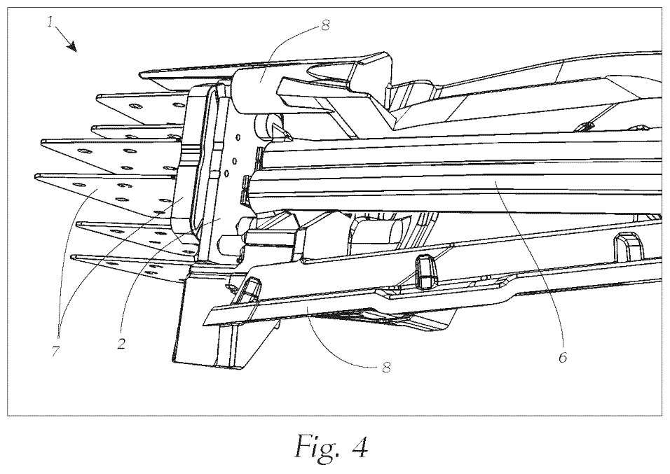

FIG. 4 shows a perspective illustration of the light module according to FIG. 3 incl. a section of a frame structure 8. This frame structure 8 is provided for guiding and at least partially attaching the light guides and can also form a visible part of a vehicle headlight design.

Furthermore, the invention relates to a method for producing a light module 1 according to the invention, comprising the following steps:
a) providing a printed circuit board 2, which is equipped with at least one light unit 3, wherein the printed circuit board 2 has at least one spacer element receiving opening 4, which passes through the printed circuit board 2 and is configured to receive a spacer element 5,
b) providing at least one spacer element 5, wherein the at least one spacer element 5 has at least two sections, namely a holding section 5b passing through the spacer element receiving opening 4 and at least one support section 5a arranged on one end of the holding section 5b, which support section is widened compared to the holding section 5b,
c) inserting the at least one spacer element 5 into the at least one spacer element receiving opening 4,
d) establishing a connection between the at least one spacer element 5 and the at least one spacer element receiving opening 4, which secures the at least one spacer element 5 against a displacement in a normal direction x to the printed circuit board 2,
e) positioning a light guide 6, which has a light entry surface 6a, on the printed circuit board 2 in such a way that the light entry surface 6a faces the light unit 3 for receiving light, wherein the light entry surface 6a of the light guide 6 is surrounded by at least one support region 6b of the light guide 6, which support region 6b of the light guide 6 is supported on the support face 5a′ of the spacer element 5 for fixing a defined normal distance d of the light entry surface 6a of the light guide 6 in relation to the light unit 3.

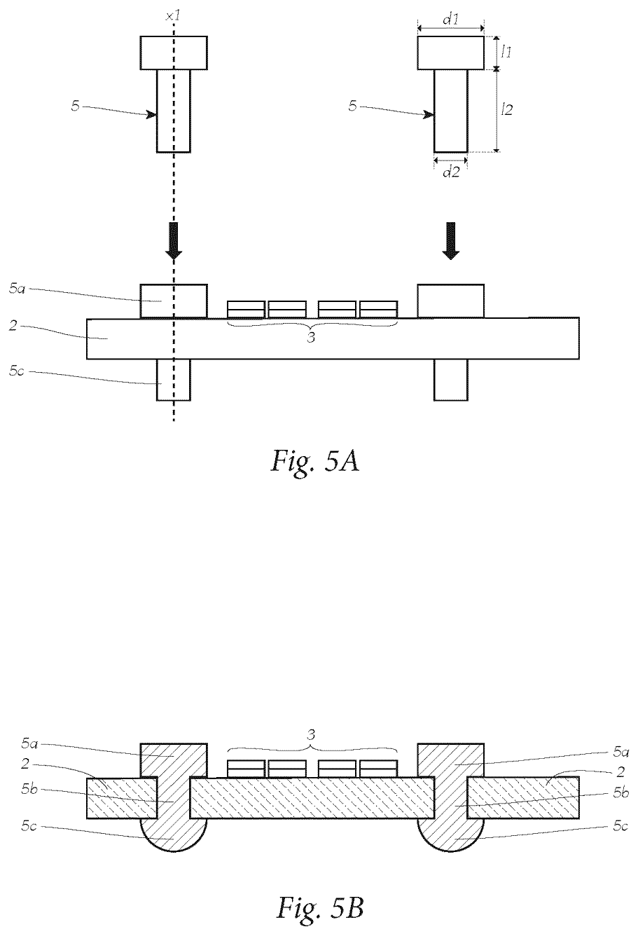

The connection according to step d) has been carried out by heat staking, for example, in the embodiment shown in FIG. 5B and 1B. In addition, it may be provided that the light guide 6 is spatially fixed in the position according to step e) in relation to the printed circuit board 2. It can be fixed by a firm connection to various components that are fixedly connected to the printed circuit board 2. For example, the connection can be made via a common housing, directly on the printed circuit board and/or other components, such as the frame element 8.

FIG. 5A shows a schematic illustration of an exemplary assembly process, i.e. a process in which the spacer elements 5 are inserted into the printed circuit board 2. It may be provided that the support section 5a and the holding section 5b of the spacer element 5 are respectively substantially cylindrical with a common longitudinal axis x1. It is preferably provided that the at least one spacer element 5 is inserted in step c) in an automated manner using optical detection of the at least one spacer element receiving opening 4. FIG. 5A shows the spacer elements 5 in two positions one above the printed circuit board 2, and one in an already inserted, but not fixed, state. FIG. 5B then shows a sectional view of an exemplary connection process, which can be carried out by heat staking.

With regard to FIG. 5A, exemplary dimensions in connection with the spacer element 5 (in the unstaked state) should also be mentioned:

It may be provided that the spacer element receiving opening 4 is designed as a hole having a circular hole diameter of between 1 mm and 2 mm and that the cross-sectional area of the support section 5a is at least four times the cross-sectional area of the holding section 5b of the spacer element 5. It may be provided that the spacer element 5 has a diameter d1 of between 2.5 and 6 mm in the region of the support section 5a, wherein the diameter is typically approx. 2.5 mm. It may be provided that the spacer element 5 has a diameter d2 of between 0.8 and 1.5 mm in the region of the holding section 5b, wherein the diameter is typically approx. 1 mm. The length 11 of the support section 5a can, for example, be between 1.4 and 2.5 mm and is typically approx. 1.5 mm. The length 12 of the holding section 5a can, for example, be between 3.5 and 5 mm and is typically approx. 4.5 mm.

It may also be provided that the distance between a spacer element receiving opening 4 and the nearest point of an associated light unit 6 is no more than 3 mm, in particular between 1.5 mm and 3 mm.

The invention is not limited to the embodiments shown, but is defined by the entire scope of protection of the claims. Individual aspects of the invention or embodiments may also be adopted and combined with each other. Any reference numbers in the claims are exemplary and merely serve to make the claims easier to read, without limiting them.

That which is claimed is:

1. A light module (1) for a motor vehicle, in particular a motor vehicle headlight, the light module (1) comprising:
a printed circuit board (2);
at least one light unit (3) arranged flat on one side of the printed circuit board (2) having a light exit surface (3a) for emitting light, wherein the light unit (3) preferably comprises at least one LED light source (3b), wherein a printed circuit board plane (yz) is formed by said side of the printed circuit board (2); and
at least one light guide (6),
wherein the printed circuit board (2) has at least one spacer element receiving opening (4), which is arranged in the vicinity of the at least one light unit (3), wherein the at least one spacer element receiving opening (4) passes through the printed circuit board (2) and is configured to receive a spacer element (5),
wherein the light module (1) further has at least one spacer element (5), which is arranged in at least one spacer element receiving opening (4), wherein the at least one spacer element (5) has at least two sections, namely a holding section (5b) passing through the spacer element receiving opening (4) and at least one support section (5a) arranged on one end of the holding section (5b), which support section is widened compared to the holding section (5b) and secures the spacer element (5) from being pushed through the spacer element receiving opening (4), wherein the support section (5a) is arranged on the same side of the printed circuit board (2) as the at least one light unit (3) and is delimited on its end facing away from the printed circuit board (2) by a flat support face (5a′), wherein this support face (5a′) is oriented substantially parallel to the printed circuit board plane (yz), and
wherein the light guide (6) has a light entry surface (6a), which faces the light unit (3) for receiving light, wherein the light entry surface (6a) of the light guide (6) is at least partially surrounded by at least one support region (6b) of the light guide (6), which support region (6b) of the light guide (6) is supported on the support face (5a′) of the spacer element (5) for fixing a defined normal distance (d) of the light entry surface (6a) of the light guide (6) in relation to the light unit (3).

2. The light module (1) according to claim 1, wherein the support section (5a) of the spacer element (5) protrudes further in the normal direction (−x) to the printed circuit board plane (yz) from the printed circuit board (2) than the light exit surface (3a) of the light unit (3) such that the support face (5a′) protrudes beyond the light exit surface (3a) in the normal direction (−x).

3. The light module (1) according to claim 1, wherein at least one projection (6b′), preferably two projections (6b′) are formed in the support region (6b) of the light guide (6), which protrude in the direction of the support face (5a′) of the spacer element (5) from the light guide (6) and are supported on the support face (5a′).

4. The light module (1) according to claim 1, wherein the holding section (5b) of the spacer element (5) is designed in such a way that it fills the spacer element receiving opening (4) in a form-fitting manner.

5. The light module (1) according to claim 1, wherein the at least one light unit (3) is surrounded by at least two, preferably exactly two, spacer element receiving openings (4), wherein these spacer element receiving openings (4) are arranged spatially around the light unit (3) in such a way that
if there are exactly two spacer element openings (4) in the vicinity of the light unit (3), the centre point of a notional connecting line between the spacer element openings (4) substantially coincides with the geometric centre of the light exit surface (3a) of the light unit (3), and/or
if there are three or more spacer element openings (4) in the vicinity of the light unit (3), the centre of a notional polygon substantially coincides with the geometric centre of the light exit surface (3a) of the light unit (3), wherein the notional polygon is formed in such a way that each spacer element opening (4) present in the vicinity of the light unit (3) forms a corner of the polygon and each corner has a straight connection to the two closest corners.

6. The light module (1) according to claim 1, wherein the light module (1) has two or more light units (3), wherein the two or more light units (3) are each associated with:
at least one, two or more spacer element receiving openings (4), each with a spacer element (5) accommodated therein, and
a light guide (6).

7. The light module (1) according to claim 1, wherein the support section (5a) and the holding section (5b) of the spacer element (5) are respectively substantially cylindrical with a common longitudinal axis (x1).

8. The light module (1) according to claim 1, wherein the distance between a spacer element receiving opening (4) and the nearest point of an associated light unit (3) is no more than 3 mm, in particular between 1.5 mm and 3 mm.

9. The light module (1) according to claim 1, wherein the spacer element receiving opening (4) is designed as a hole having a circular hole diameter of between 1 mm and 2 mm.

10. The light module (1) according to claim 1, wherein the cross-sectional area of the support section (5a) is at least four times the cross-sectional area of the holding section (5b) of the spacer element (5).

11. The light module (1) according to claim 1, wherein the holding section (5b) of the spacer element (5) is firmly fixed in the spacer element receiving opening (4).

12. The light module (1) according to claim 1, wherein the spacer element (5) also has a securing section (5c), which securing section (5c) is arranged on the end of the holding section (5b) opposite the support section (5a), wherein the securing section (5c) is widened relative to the holding section (5b).

13. A method for producing a light module (1) according to claim 1, comprising the following steps:
a) providing a printed circuit board (2), which is equipped with at least one light unit (3), wherein the printed circuit board (2) has at least one spacer element receiving opening (4), which passes through the printed circuit board (2) and is configured to receive a spacer element (5);
b) providing at least one spacer element (5), wherein the at least one spacer element (5) has at least two sections, namely a holding section (5b) passing through the spacer element receiving opening (4) and at least one support section (5a) arranged on one end of the holding section (5b), which support section is widened compared to the holding section (5b);
c) inserting the at least one spacer element (5) into the at least one spacer element receiving opening (4);
d) establishing a connection between the at least one spacer element (5) and the at least one spacer element receiving opening (4), which secures the at least one spacer element (5) against a displacement in a normal direction (x) to the printed circuit board (2); and
e) positioning a light guide (6), which has a light entry surface (6a), on the printed circuit board (2) in such a way that the light entry surface (6a) faces the light unit (3) for receiving light, wherein the light entry surface (6a) of the light guide (6) is surrounded by at least one support region (6b) of the light guide (6), which support region (6b) of the light guide (6) is supported on the support face (5a′) of the spacer element (5) for fixing a defined normal distance (d) of the light entry surface (6a) of the light guide (6) in relation to the light unit (3).

14. The method according to claim 13, wherein the light guide (6) is spatially fixed in the position according to step e) in relation to the printed circuit board (2).

15. The method according to claim 13, wherein the at least one spacer element (5) is inserted in step c) in an automated manner using optical detection of the at least one spacer element receiving opening (4).
